(19) United States
(12) Patent Application Publication
(10) Pub. No.: US 2026/0280573 A1
(43) Pub. Date: Sep. 17, 2026

(54) SEMICONDUCTOR DEVICE AND METHOD

(71) Applicant: Kioxia Corporation, Tokyo (JP)

(72) Inventor: Shoun MATSUNAGA, Minato Tokyo (JP)

(73) Assignee: Kioxia Corporation, Tokyo (JP)

(21) Appl. No.: 19/321,614

(22) Filed: Sep. 8, 2025

(30) Foreign Application Priority Data
Mar. 17, 2025 (JP) 2025-042412

(51) Int. Cl. H03L 7/18; H03L 7/081; H03L 7/089; H03L 7/091; H03L 7/099

(52) U.S. Cl. CPC H03L 7/18; H03L 7/081; H03L 7/0895; H03L 7/091; H03L 7/099

(57) ABSTRACT

According to the embodiment, an oscillation circuit oscillates a clock signal with a frequency corresponding to a potential of a control signal. A control circuit executes calibration of a frequency of the clock signal when the potential of the control signal is set to a calibration potential. After completion of the calibration, a frequency divider circuit adjusts an initial phase error based on the phase of the reference clock signal and generates a second clock signal that is a clock signal obtained by performing frequency-division of the first clock signal to include the adjusted initial phase error. A phase comparator circuit compares phases between the reference clock signal and the second clock signal. A charge pump circuit supplies a current corresponding to a result of the comparison. A filter circuit converts the current from the charge pump circuit into the control signal.

### CROSS-REFERENCE TO RELATED APPLICATIONS

This application is based upon and claims the benefit of priority from Japanese Patent Application No. 2025-042412, filed on Mar. 17, 2025, the entire contents of which are incorporated herein by reference.

### FIELD

Embodiments described herein relate generally to a semiconductor device and a method.

### BACKGROUND

A phase locked loop (PLL) circuit has been known as a semiconductor device that generates a clock signal synchronized with a reference clock signal. With the miniaturization of processes in recent years, the variation width of each loop parameter of the PLL circuit has increased, and thereby the variation width of the PLL loop bandwidth has also increased.

In order to reduce the phase jitter of the clock signal output from the PLL circuit, it is important to reduce the PLL loop bandwidth. However, reduction of the PLL loop bandwidth may cause the lock-up time to be prolonged, and it is difficult to satisfy the specification regarding the lock-up time.

### BRIEF DESCRIPTION OF THE DRAWINGS

FIG. 1 is a diagram illustrating an example of a configuration of a PLL circuit which is a semiconductor device according to the first embodiment;

FIG. 2 is a diagram illustrating changes in a frequency error of a low-speed feedback clock signal and a phase error of the low-speed feedback clock signal during operation of a feedback loop;

FIG. 3 is a diagram for describing several enable signals used in the PLL circuit according to the first embodiment;

FIG. 4 is a flowchart illustrating an example of an operation of the control circuit according to the first embodiment;

FIG. 5 is a diagram illustrating an example of detailed waveforms of various signals used in a frequency divider circuit according to the first embodiment in a case where the oscillation frequency of the voltage control oscillation circuit at the time of completion of the calibration is lower than a target frequency;

FIG. 6 is a diagram illustrating an example of detailed waveforms of various signals used in the frequency divider circuit according to the first embodiment in a case where the oscillation frequency of the voltage control oscillation circuit at the time of the completion of the calibration is higher than a target frequency;

FIG. 7 is a diagram illustrating an example of a configuration of the PLL circuit according to the second embodiment;

FIG. 8 is a flowchart illustrating an example of an operation of the control circuit according to the second embodiment; and

FIG. 9 is a diagram illustrating an example of detailed waveforms of various signals used in a frequency divider circuit according to the second embodiment in a case where the oscillation frequency of the voltage control oscillation circuit at the time of completion of the calibration is higher than a target frequency.

### DETAILED DESCRIPTION

According to the present embodiment, a semiconductor device includes an oscillation circuit, a control circuit, a frequency divider circuit, a phase comparator circuit, a charge pump circuit, and a filter circuit. The oscillation circuit is configured to oscillate a clock signal with a frequency corresponding to a potential of a control signal. The control circuit is configured to execute calibration of a first frequency when a potential of the control signal is set to a calibration potential. The first frequency is a frequency of a first clock signal. The first clock signal is the clock signal oscillated by the oscillation circuit. The frequency divider circuit is configured to, after completion of the calibration, adjust an initial phase error based on a phase of a reference clock signal and generate a second clock signal being a clock signal obtained by performing frequency-division of the first clock signal to include the adjusted initial phase error. The phase comparator circuit is configured to, after completion of the calibration, compare phases between the reference clock signal and the second clock signal. The charge pump circuit is configured to, after completion of the calibration, supply a current corresponding to a result of the comparison. The filter circuit is configured to, after completion of the calibration, convert a current from the charge pump circuit into the control signal.

Hereinafter, a semiconductor device and a method according to embodiments will be described in detail with reference to the accompanying drawings. Note that the present disclosure is not limited by these embodiments.

### First Embodiment

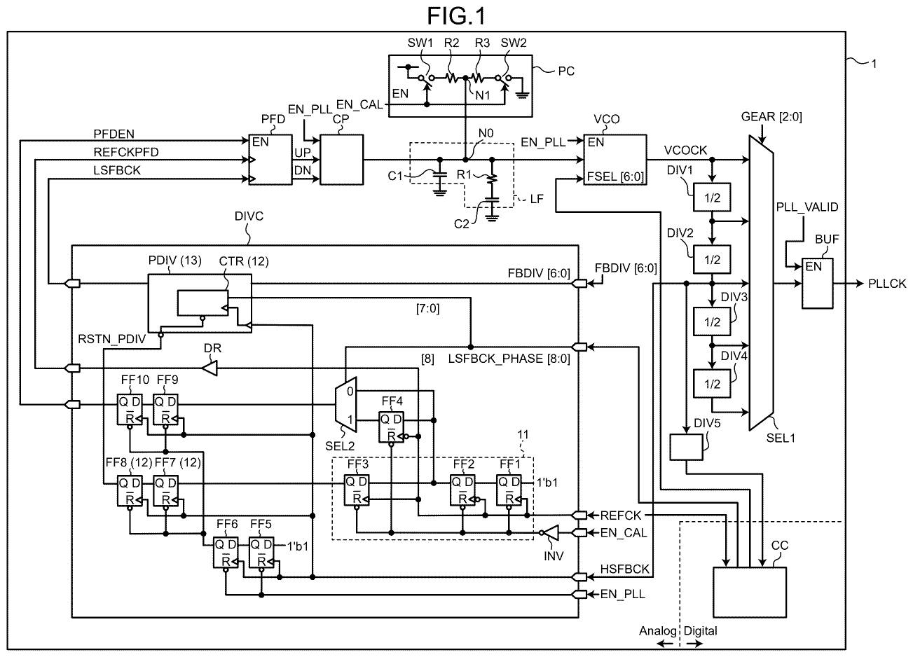

FIG. 1 is a diagram illustrating an example of a configuration of a PLL circuit 1 which is a semiconductor device according to the first embodiment.

In the PLL circuit 1, various enable signals and binary signals are used. Whether the various enable signals are controlled by positive logic or negative logic can be designed in any manner. The relation between the level and the value of the binary signal is designed in any manner. In the present disclosure, it is assumed that various enable signals are controlled by positive logic. In addition, as an example, a state in which the binary signal is at the High level corresponds to “1”, and a state in which the binary signal is at the Low level corresponds to “0”. In addition, action of changing the level of the binary signal from the Low level to the High level is referred to as asserting. Action of changing the level of the binary signal from the High level to the Low level is referred to as deasserting.

The PLL circuit 1 includes a phase comparator circuit PFD, a charge pump circuit CP, a loop filter LF, a voltage control oscillation circuit VCO, a frequency divider circuit DIVC, a calibration power supply PC, and a control circuit CC. The voltage control oscillation circuit VCO is an example of an oscillation circuit. The loop filter LF is an example of a filter circuit.

A basic operation of the PLL circuit 1 will be briefly described. In the above configuration, the voltage control oscillation circuit VCO outputs a clock signal VCOCK with a frequency corresponding to the potential of the control voltage signal input from the loop filter LF. The clock signal VCOCK is frequency-divided by the frequency divider circuit DIVC or the like, and is input to the phase comparator circuit PFD as a low-speed feedback clock signal LSFBCK. The phase comparator circuit PFD receives a reference clock signal REFCKPFD in addition to the low-speed feedback clock signal LSFBCK. The phase comparator circuit PFD compares the phases between the low-speed feedback clock signal LSFBCK and the reference clock signal REFCKPFD, and generates two control pulse signals (up signal UP, down signal DN) based on the comparison result (phase difference). The charge pump circuit CP charges or discharges capacitive elements C1 and C2 included in the loop filter LF based on the two control pulse signals. The potential of the node N0 included in the loop filter LF changes by charging or discharging of the capacitive elements C1 and C2. The potential of the node N0 is input to the voltage control oscillation circuit VCO as a new control voltage of the voltage control oscillation circuit VCO. The voltage control oscillation circuit VCO changes the oscillation frequency of the clock signal VCOCK in accordance with the new control voltage.

In this manner, the phase comparator circuit PFD, the charge pump circuit CP, the loop filter LF, the voltage control oscillation circuit VCO, and the frequency divider circuit DIVC constitute a feedback loop. By the operation of the feedback loop, the clock signal VCOCK with the predetermined frequency synchronized with the reference clock signal REFCKPFD is stably output from the voltage control oscillation circuit VCO.

The control voltage signal is an example of the control signal.

The completion of synchronization of the clock signal VCOCK with the reference clock signal REFCKPFD by the operation of the feedback loop is referred to as lock-up. After the lock-up, the clock signal VCOCK output from the voltage control oscillation circuit VCO is subjected to frequency division or the like as appropriate, and is output from the PLL circuit 1 as a PLL clock signal PLLCK.

During the operation of the feedback loop, the frequency error of the low-speed feedback clock signal LSFBCK and the phase error of the low-speed feedback clock signal LSFBCK continuously change until the lock-up is completed.

The frequency error of the low-speed feedback clock signal LSFBCK is an error of the frequency of the low-speed feedback clock signal LSFBCK based on the frequency of the reference clock signal REFCKPFD, and more specifically, is a value obtained by subtracting the frequency of the reference clock signal REFCKPFD from the frequency of the low-speed feedback clock signal LSFBCK. The phase error of the low-speed feedback clock signal LSFBCK is an error of the phase of the low-speed feedback clock signal LSFBCK based on the phase of the reference clock signal REFCKPFD, and more specifically, is a value obtained by subtracting the phase of the reference clock signal REFCKPFD from the phase of the low-speed feedback clock signal LSFBCK.

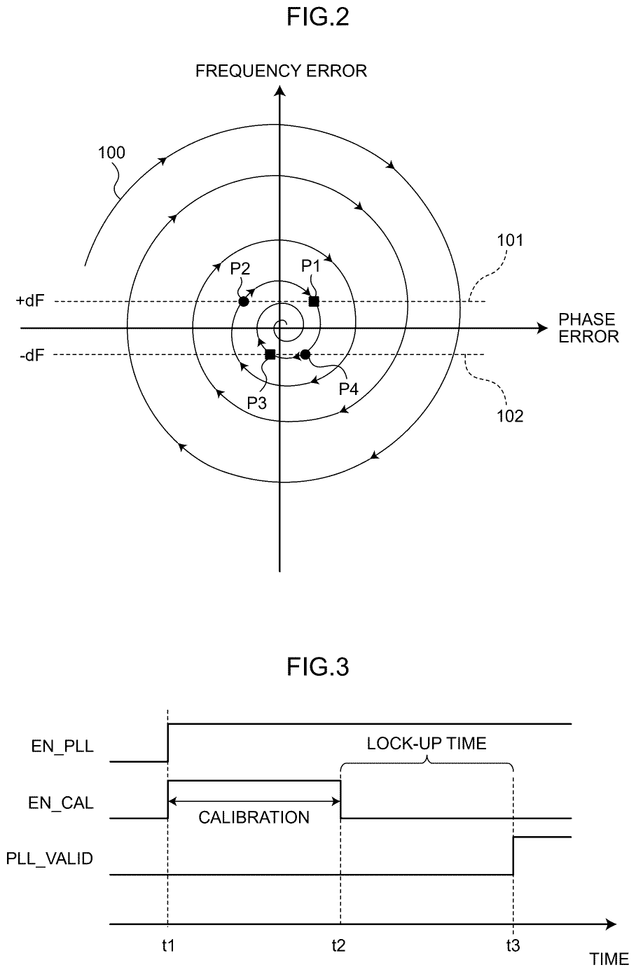

FIG. 2 is a diagram for describing changes in the frequency error of the low-speed feedback clock signal LSFBCK and the phase error of the low-speed feedback clock signal LSFBCK during the operation of the feedback loop according to the first embodiment. The horizontal axis indicates a phase error of the low-speed feedback clock signal LSFBCK. The vertical axis indicates a frequency error of the low-speed feedback clock signal LSFBCK.

In the operation of the feedback loop, the frequency error and the phase error may change in a direction toward the center of a spiral 100 (that is, the point of origin in FIG. 2) along the path illustrated in the spiral 100. When both the magnitude of the frequency error and the magnitude of the phase error become equal to or less than a predetermined value (ideally, 0), the lock-up is considered to be completed. The farther the pair of the frequency error and the phase error at the start of the operation of the feedback loop is from the center of the spiral 100 (that is, the point where both the magnitude of the frequency error and the magnitude of the phase error are 0), the longer the time required for the lock-up.

In the first embodiment, first, the control circuit CC executes calibration for suppressing a frequency error in cooperation with the calibration power supply PC. After the completion of the calibration, the frequency divider circuit DIVC starts generating the low-speed feedback clock signal LSFBCK in which the phase error is adjusted to a small value. Thus, the PLL circuit 1 suppresses both the frequency error and the phase error at the start of the operation of the feedback loop. Therefore, changes in the frequency error and the phase error due to the operation of the feedback loop are started from a point as close to the center of the spiral 100 as possible. As a result, the time required for the lock-up is shortened.

Hereinafter, the frequency error at the start of the operation of the feedback loop is referred to as an initial frequency error. The phase error at the start of the operation of the feedback loop is referred to as an initial phase error.

In the first embodiment, the frequency divider circuit DIVC further controls the sign of the initial phase error in accordance with the sign of the initial frequency error in order to further shorten the time required for the lock-up. More specifically, in a case where the sign of the initial frequency error is positive, the frequency divider circuit DIVC adjusts the initial phase error such that the sign of the initial phase error becomes positive. In a case where the sign of the initial frequency error is negative, the frequency divider circuit DIVC adjusts the initial phase error such that the sign of the initial phase error becomes negative.

According to the example illustrated in FIG. 2, in a case where, for example, the initial frequency error is +dF, a change in the frequency error and the phase error due to the operation of the feedback loop is started from an intersection P1 out of the intersection P1 and an intersection P2. The intersections P1 and P2 each indicate a point where the spiral 100 and the line 101 indicating the frequency error being +dF intersect. The intersection P1 is closer to the center in the path illustrated in the spiral 100 than the intersection P2. Therefore, the time required for the lock-up is shortened as compared with the case where the change in the frequency error and the phase error due to the operation of the feedback loop is started from the intersection P2.

In a case where, for example, the initial frequency error is −dF, a change in the frequency error and the phase error due to the operation of the feedback loop is started from an intersection P3 out of the intersection P3 and an intersection P4. The intersections P3 and P4 each indicate a point where the spiral 100 and the line 102 indicating the frequency error being −dF intersect. The intersection P3 is closer to the center in the path illustrated in the spiral 100 than the intersection P4. Therefore, the time required for the lock-up is shortened as compared with the case where the change in the frequency error and the phase error due to the operation of the feedback loop is started from the intersection P4.

As described above, the frequency divider circuit DIVC determines the sign of the initial phase error in accordance with the sign of the initial frequency error, and thereby the time required for the lock-up can be further shortened. Hereinafter, the time required for the lock-up is referred to as a lock-up time.

In the PLL circuit 1, various enable signals including an enable signal EN_CAL for calibration are used. For easy understanding, a main enable signal used in the PLL circuit 1 including the enable signal EN_CAL will be described.

FIG. 3 is a diagram for describing several enable signals used in the PLL circuit 1 according to the first embodiment. This drawing illustrates waveforms of an enable signal EN_PLL, an enable signal EN_CAL, and an enable signal PLL_VALID.

The enable signal EN_PLL is an enable signal for the PLL circuit 1 to operate.

The enable signal EN_CAL is an enable signal for the PLL circuit 1 to execute calibration.

The enable signal PLL_VALID is an enable signal for the PLL circuit 1 to output the clock signal PLLCK synchronized with the reference clock signal REFCK.

These enable signals are caused to transition, for example, as illustrated in FIG. 3. Specifically, when the PLL circuit 1 is activated, the enable signal EN_PLL is asserted and the enable signal EN_CAL is asserted (time t1). The calibration is started in response to assertion of the enable signal EN_CAL.

Thereafter, the enable signal EN_CAL is deasserted in response to the completion of the calibration (time t2). The operation of the feedback loop is started in response to the deassertion of the enable signal EN_CAL.

When the lock-up is completed, the enable signal PLL_VALID is asserted (time t3). In response to the assertion of the enable signal PLL_VALID, the PLL circuit 1 starts outputting the clock signal PLLCK.

In a case where each enable signal is caused to transition as described above, the time from time t2 when the enable signal EN_CAL is deasserted to time t3 when the enable signal PLL_VALID is asserted corresponds to the lock-up time.

The description returns to FIG. 1. A configuration of the PLL circuit 1 according to the embodiment will be described in detail.

The phase comparator circuit PFD receives the reference clock signal REFCKPFD and the low-speed feedback clock signal LSFBCK from the frequency divider circuit DIVC. The phase comparator circuit PFD receives an enable signal PFDEN from the frequency divider circuit DIVC.

The phase comparator circuit PFD is enabled by the enable signal PFDEN. After being enabled, the phase comparator circuit PFD compares the phase of the reference clock signal REFCKPFD with the phase of the low-speed feedback clock signal LSFBCK. Then, the phase comparator circuit PFD generates the up signal UP and the down signal DN based on the result of the comparison of the phases. Specifically, both the up signal UP and the down signal DN are maintained at the Low level before being enabled, and the phase comparator circuit PFD detects the timing of the rising edge (or falling edge) of the reference clock signal REFCKPFD and the timing of the rising edge (or falling edge) of the low-speed feedback clock signal LSFBCK after being enabled. The phase comparator circuit PFD can be designed in any manner as to which timing of a rising edge or a falling edge of each input clock signal is detected. In the description of the present specification, as an example, the phase comparator circuit PFD detects the timing of the rising edge of each input clock signal. The phase comparator circuit PFD asserts the up signal UP at the same time as detecting the timing of the rising edge of the reference clock signal REFCKPFD, asserts the down signal DN at the same time as detecting the timing of the rising edge of the low-speed feedback clock signal LSFBCK, and deasserts both the up signal UP and the down signal DN at the same timing a certain period of time after both the up signal UP and the down signal DN transitioned to the High level. Thus, the pulse width of the up signal UP and the pulse width of the down signal DN are different by the magnitude of the phase error. The phase comparator circuit PFD outputs the generated up signal UP and the generated down signal DN to the charge pump circuit CP.

The charge pump circuit CP receives the enable signal EN_PLL. The charge pump circuit CP receives the up signal UP and the down signal DN from the phase comparator circuit PFD.

The charge pump circuit CP is enabled by an enable signal EN_PLL. After being enabled, the charge pump circuit CP supplies a current to the loop filter LF based on the up signal UP and the down signal DN. The charge pump circuit CP charges the capacitive elements C1 and C2 included in the loop filter LF while the up signal UP is at the High level. The charge pump circuit CP discharges the capacitive elements C1 and C2 while the down signal DN is at the High level. Specifically, the charge pump circuit CP charges the capacitive elements C1 and C2 in a case where the pulse width of the up signal UP is longer than the pulse width of the down signal DN, discharges the capacitive elements C1 and C2 in a case where the pulse width of the up signal UP is shorter than the pulse width of the down signal DN, and in a case where the pulse width of the up signal UP is the same as the pulse width of the down signal DN, and a current for charging the capacitive elements C1 and C2 and a current for discharging the capacitive elements C1 and C2 canceling each other, supplies substantially no current to the capacitive elements C1 and C2, and performs neither charging nor discharging. As described above, even in a case where the phase error is 0 (zero), the current for charging and the current for discharging the capacitive elements C1 and C2 flow only for a certain period of time in the charge pump circuit CP. Therefore, a dead zone does not occur.

Note that, in order to eliminate the dead zone in which the charge pump circuit CP cannot supply the current when the phase error is near 0 (zero), the configuration in which the pulse width for a certain time is secured as the up signal UP and the down signal DN in the phase comparator circuit PFD is described as an example. However, the present disclosure is not limited to this example. The phase comparator circuit PFD and the charge pump circuit CP to which various methods for eliminating the dead zone are applied can be configured.

The loop filter LF includes the node N0, the capacitive elements C1 and C2, and the resistor R1. Each of the capacitive elements C1 and C2 includes two terminals. One of the two terminals included in the capacitive element C1 is connected to the node N0, and the other terminal is connected to the ground potential. The resistor R1 includes two terminals. One of the two terminals included in the resistor R1 is connected to the node N0, and the other is connected to one of the two terminals included in the capacitive element C2. The other of the two terminals included in the capacitive element C2 is connected to the ground potential. With this configuration, the potential of the node N0 of the loop filter LF changes with charging and discharging of the capacitive elements C1 and C2. The potential of the node N0 is input to the voltage control oscillation circuit VCO as a control voltage signal of the voltage control oscillation circuit VCO. The loop filter LF is configured to convert the current supplied from the charge pump circuit CP into a control voltage signal.

The voltage control oscillation circuit VCO receives the enable signal EN_PLL. The voltage control oscillation circuit VCO receives the potential of the node N0 as a control voltage signal. The voltage control oscillation circuit VCO receives a frequency setting signal FSEL from the control circuit CC. Note that the frequency setting signal FSEL is controlled by the control circuit CC such that the oscillation frequency of the voltage control oscillation circuit VCO is closest to the target frequency at the time of calibration, and the setting value is held even after the completion of the calibration.

The voltage control oscillation circuit VCO is enabled by the enable signal EN_PLL. After being enabled by the enable signal EN_PLL, the voltage control oscillation circuit VCO starts outputting a clock signal VCOCK with a frequency corresponding to the control voltage.

In the first embodiment, it is assumed that the PLL circuit 1 is configured to generate a clock signal PLLCK with a frequency higher than the frequency of the reference clock signal REFCK by multiplying the frequency of the reference clock signal REFCK. Therefore, the voltage control oscillation circuit VCO is configured to output the clock signal VCOCK with a frequency significantly higher than the frequency of the reference clock signal REFCK.

In the operation of the feedback loop, in a case where the phase of the low-speed feedback clock signal LSFBCK is delayed from the phase of the reference clock signal REFCKPFD, that is, in a case where the sign of the phase error of the low-speed feedback clock signal LSFBCK is negative, the phase comparator circuit PFD instructs the charge pump circuit CP to generate a pulse of the up signal UP longer than the pulse width of the down signal DN and charge the capacitive elements C1 and C2. The charge pump circuit CP charges the capacitive elements C1 and C2 in accordance with the up signal UP and the down signal DN, thereby increasing the potential of the node N0. The oscillation frequency of the voltage control oscillation circuit VCO increases as the potential of the node N0 increases.

On the other hand, in a case where the phase of the low-speed feedback clock signal LSFBCK is ahead of the phase of the reference clock signal REFCKPFD, that is, in a case where the sign of the phase error of the low-speed feedback clock signal LSFBCK is positive, the phase comparator circuit PFD instructs the charge pump circuit CP to generate a pulse of the down signal DN longer than the pulse width of the up signal UP and discharge the capacitive elements C1 and C2. The charge pump circuit CP discharges the capacitive elements C1 and C2 in accordance with the up signal UP and the down signal DN, whereby the potential of the node N0 decreases. The oscillation frequency of the voltage control oscillation circuit VCO decreases as the potential of the node N0 decreases.

The PLL circuit 1 further includes four frequency dividers DIV1 to DIV4 serially connected, a selector SEL1, a buffer circuit BUF, and a frequency divider DIV5. The frequency division ratio of each of the four frequency dividers DIV1 to DIV4 is, for example, ½. Thus, each of the four frequency dividers DIV1 to DIV4 reduces the frequency of the input clock signal to ½. The frequency division ratio of the frequency divider DIV5 is designed in any manner by a designer.

The selector SEL1 includes five input terminals and one output terminal. The five input terminals are a terminal to which the clock signal VCOCK is input, a terminal to which the clock signal VCOCK via the frequency divider DIV1 is input, a terminal to which the clock signal VCOCK via the frequency divider DIV1 and the frequency divider DIV2 is input, a terminal to which the clock signal VCOCK via the frequency divider DIV1, the frequency divider DIV2, and the frequency divider DIV3 is input, and a terminal to which the clock signal VCOCK via the frequency divider DIV1, the frequency divider DIV2, the frequency divider DIV3, and the frequency divider DIV4 is input. The selector SEL1 further includes a selection signal terminal. A 3-bit selection signal GEAR is input to the selection signal terminal. The selection signal GEAR is a signal for selecting one of the five clock signals input to the five input terminals. The clock signal selected by the selection signal GEAR is output from the output terminal of the selector SEL1. Specifically, the selector SEL1 selects one of: the clock signal VCOCK, a clock signal obtained by frequency-dividing the clock signal VCOCK by two, a clock signal obtained by frequency-dividing the clock signal VCOCK by four, a clock signal obtained by frequency-dividing the clock signal VCOCK by eight, and a clock signal obtained by frequency-dividing the clock signal VCOCK by 16, and outputs the selected clock signal.

The buffer circuit BUF receives the enable signal PLL_VALID. In addition, the buffer circuit BUF receives the clock signal output from the output terminal of the selector SEL1. The buffer circuit BUF is enabled by the enable signal PLL_VALID. The buffer circuit BUF outputs the clock signal output from the output terminal of the selector SEL1 after being enabled by the enable signal PLL_VALID. The clock signal output by the buffer circuit BUF is output from the PLL circuit 1 as a clock signal PLLCK.

The frequency divider circuit DIVC receives, as a high-speed feedback clock signal HSFBCK, the clock signal VCOCK via the frequency divider DIV1 and the frequency divider DIV2, that is, the clock signal obtained by frequency-dividing the clock signal VCOCK by four. In addition, the frequency divider circuit DIVC receives an enable signal EN_PLL, an enable signal EN_CAL, a reference clock signal REFCK, a control signal FBDIV, and a control signal LSFBCK_PHASE.

The frequency divider circuit DIVC includes 10 flip-flops FF1, FF2, FF3, FF4, FF5, FF6, FF7, FF8, FF9, and FF10, an inverter INV, a selector SEL2, a driver DR, and a programmable frequency divider PDIV. Each of the 10 flip-flops FF1, FF2, FF3, FF4, FF5, FF6, FF7, FF8, FF9, and FF10 is a D flip-flop including a Q terminal, a D terminal, a clock terminal, and a reset terminal.

The driver DR receives the reference clock signal REFCK. The reference clock signal REFCK output from the driver DR is input to the phase comparator circuit PFD as the reference clock signal REFCKPFD.

The enable signal EN_CAL is input to the inverter INV. The inverter INV inverts the enable signal EN_CAL. The enable signal EN_CAL inverted by the inverter INV is commonly input to the reset terminal of the flip-flop FF1, the reset terminal of the flip-flop FF2, the reset terminal of the flip-flop FF3, and the reset terminal of the flip-flop FF4.

A binary signal indicating “1 (High level)” is input to the D terminal of the flip-flop FF1. The Q terminal of the flip-flop FF1 is connected to the D terminal of the flip-flop FF2. The Q terminal of the flip-flop FF2 is connected to the D terminal of the flip-flop FF3 and the D terminal of the flip-flop FF4.

The reference clock signal REFCK is input to the clock terminal of the flip-flop FF1 and the clock terminal of the flip-flop FF3. A clock signal obtained by inverting the reference clock signal REFCK is input to a clock terminal of the flip-flop FF2 and a clock terminal of the flip-flop FF4.

The enable signal EN_PLL is input to the reset terminal of the flip-flop FF5 and the reset terminal of the flip-flop FF6. The high-speed feedback clock signal HSFBCK is input to the clock terminal of the flip-flop FF5 and the clock terminal of the flip-flop FF6.

A binary signal indicating “1 (High level)” is input to the D terminal of the flip-flop FF5. The Q terminal of the flip-flop FF5 is connected to the D terminal of the flip-flop FF6.

The Q terminal of the flip-flop FF6 is commonly connected to the reset terminal of the flip-flop FF7, the reset terminal of the flip-flop FF8, the reset terminal of the flip-flop FF9, and the reset terminal of the flip-flop FF10. The signal output from the Q terminal of the flip-flop FF6 is a signal synchronized with the high-speed feedback clock signal HSFBCK, and is used for the synchronous reset release of the flip-flop FF7, the flip-flop FF8, the flip-flop FF9, and the flip-flop FF10. It is sufficient that the reset release of the flip-flop FF7, the flip-flop FF8, the flip-flop FF9, and the flip-flop FF10 has been completed before the enable signal EN_CAL is deasserted. Therefore, it is possible to adopt a configuration that the flip-flop FF5 and the flip-flop FF6 are omitted, and the enable signal EN_PLL is directly connected to the reset terminal of the flip-flop FF7, the reset terminal of the flip-flop FF8, the reset terminal of the flip-flop FF9, and the reset terminal of the flip-flop FF10 to perform the asynchronous reset release.

A high-speed feedback clock signal HSFBCK is input to the clock terminal of the flip-flop FF7, the clock terminal of the flip-flop FF8, the clock terminal of the flip-flop FF9, and the clock terminal of the flip-flop FF10.

The Q terminal of the flip-flop FF3 is connected to the D terminal of the flip-flop FF7. The Q terminal of the flip-flop FF7 is connected to the D terminal of the flip-flop FF8.

The selector SEL2 includes two input terminals, one output terminal, and a selection signal terminal. One of the two input terminals of the selector SEL2 is connected to the Q terminal of the flip-flop FF2. The other of the two input terminals of the selector SEL2 is connected to the Q terminal of the flip-flop FF4. A 1-bit selection signal is input to the selection signal terminal of the selector SEL2. One of the signals input to the two input terminals of the selector SEL2 is selected by the selection signal, and the selected signal is output from the output terminal. In one example, in a case where the selection signal is “0”, the signal input from the Q terminal of the flip-flop FF2 is selected, and in a case where the selection signal is “1”, the signal input from the Q terminal of the flip-flop FF4 is selected.

The output terminal of the selector SEL2 is connected to the D terminal of the flip-flop FF9. The Q terminal of the flip-flop FF9 is connected to the D terminal of the flip-flop FF10. The signal output from the Q terminal of the flip-flop FF10 is input to the phase comparator circuit PFD as an enable signal PFDEN.

The programmable frequency divider PDIV includes a reset terminal, a clock terminal, and two control signal terminals. The programmable frequency divider PDIV includes a counter CTR. The counter CTR includes a reset terminal, a clock terminal, and a control signal terminal.

The reset terminal of the programmable frequency divider PDIV is connected to the Q terminal of the flip-flop FF8. The signal input to the reset terminal of the programmable frequency divider PDIV is input to the reset terminal of the counter CTR inside the programmable frequency divider PDIV. Thus, the reset release of the programmable frequency divider PDIV and the counter CTR is implemented by the signal output from the Q terminal of the flip-flop FF8. The signal output from the Q terminal of the flip-flop FF8 is referred to as a reset release signal RSTN_PDIV.

The high-speed feedback clock signal HSFBCK is input to the clock terminal of the programmable frequency divider PDIV. The high-speed feedback clock signal HSFBCK input to the clock terminal of the programmable frequency divider PDIV is input to the clock terminal of the counter CTR inside the programmable frequency divider PDIV.

The control signal FBDIV is input to one of the two control signal terminals of the programmable frequency divider PDIV. The control signal FBDIV is a signal for setting a frequency division ratio in the programmable frequency divider PDIV. In one example, the control signal FBDIV is a signal with a 7-bit width.

A signal for setting a value to the counter CTR is input to the other of the two control signal terminals of the programmable frequency divider PDIV. After the reset release, the counter CTR starts counting the clock pulses of the high-speed feedback clock signal HSFBCK. Then, at the timing when the count value by the counter CTR reaches the setting value, the programmable frequency divider PDIV starts frequency-dividing the high-speed feedback clock signal HSFBCK at the set frequency division ratio and outputting a signal generated by the frequency division of the high-speed feedback clock signal HSFBCK.

The signal obtained by frequency-dividing the high-speed feedback clock signal HSFBCK and generated by the programmable frequency divider PDIV is input to the phase comparator circuit PFD as the low-speed feedback clock signal LSFBCK.

The control signal LSFBCK_PHASE is generated by the control circuit CC. The control signal LSFBCK_PHASE is a signal obtained by bit-combining the selection signal of the selector SEL2 and the setting value of the counter CTR. In one example, the control signal LSFBCK_PHASE is a signal with a 9-bit width. Thus, the control signal LSFBCK_PHASE transfers 9-bit information. The lower 8 bits of the control signal LSFBCK_PHASE are input to the programmable frequency divider PDIV as a setting value of the counter CTR, and the most significant 1 bit of the control signal LSFBCK_PHASE is input to the selector SEL2 as a selection signal. The method of the bit division of the control signal LSFBCK_PHASE is not limited thereto.

The calibration power supply PC includes two switches SW1 and SW2, two resistors R2 and R3, and a node N1. The calibration power supply PC receives the enable signal EN_CAL.

The node N1 is connected to the node N0.

Each of the two resistors R2 and R3 includes two terminals. One of the two terminals included in the resistor R2 is connected to the node N1, and the other of the two terminals included in the resistor R2 is connected to the power supply potential (VDD) via the switch SW1. One of the two terminals included in the resistor R3 is connected to the node N1, and the other of the two terminals included in the resistor R3 is connected to the ground potential via the switch SW2.

Both of the two switches SW1 and SW2 are turned on when the enable signal EN_CAL is asserted. When the two switches SW1 and SW2 are turned on, the node N1 is a predetermined potential (for example, VDD/2) determined by the resistance value of the resistor R2 and the resistance value of the resistor R3. As a result, while the enable signal EN_CAL is maintained at the High level (that is, while calibration is being executed), the control voltage input to the voltage control oscillation circuit VCO is fixed to a predetermined potential. Hereinafter, the predetermined potential is referred to as a calibration potential. Both the up signal UP and the down signal DN, which are inputs of the charge pump circuit CP, are maintained at the Low level during the calibration period. Therefore, the charge pump circuit CP enters a state of not outputting a current (that is, the output of the charge pump circuit CP is in a high impedance state), which does not interfere with the operation of fixing the control voltage input to the voltage control oscillation circuit VCO to the calibration potential.

When the enable signal EN_CAL is deasserted, both of the two switches SW1 and SW2 are turned off. As a result, the potentials of the nodes N1 and N0 are changed by the current supplied from the charge pump circuit CP. Thus, the feedback loop can be operated.

The clock signal VCOCK output from the voltage control oscillation circuit VCO is frequency-divided at a predetermined frequency division ratio by frequency division by each of the frequency divider DIV1, the frequency divider DIV2, and the frequency divider DIV5, and then input to the control circuit CC. The reference clock signal REFCK is input to the control circuit CC. In the calibration, the control circuit CC counts the clock pulse of the frequency-divided clock signal VCOCK for one cycle or several cycles of the reference clock signal REFCK, and compares the frequency of the clock signal VCOCK with the target frequency of the clock signal VCOCK by comparing the count with the target count value. Then, the control circuit CC brings the frequency of the clock signal VCOCK close to the target frequency by adjusting the value of the frequency setting signal FSEL in accordance with the comparison result. When the magnitude of the error in the frequency of the clock signal VCOCK, that is, the absolute value of the value obtained by subtracting the target frequency from the frequency of the clock signal VCOCK is equal to or less than a predetermined value, the calibration is completed.

The target frequency of the clock signal VCOCK is determined based on the frequency of the reference clock signal REFCK. For example, when the error of the frequency of the clock signal VCOCK is set to 0, the frequency error of the low-speed feedback clock signal LSFBCK can be set to 0. Thus, in the calibration, the magnitude of the frequency error of the low-speed feedback clock signal LSFBCK is small.

The control circuit CC generates the control signal LSFBCK_PHASE in accordance with the sign of the error in the frequency of the clock signal VCOCK at the time of the completion of the calibration.

As described above, the most significant bit information of the 9-bit information transferred by the control signal LSFBCK_PHASE is used as the selection signal of the selector SEL2, and the lower 8-bit information is used as the setting value of the counter CTR.

In a case where the sign of the error in the frequency of the clock signal VCOCK at the time of the completion of the calibration is negative, the control circuit CC sets all bits of the control signal LSFBCK_PHASE to zero. The control circuit CC sets the selection signal of the selector SEL2 to “0” and sets the setting value of the counter CTR to “0” by setting all bits of the control signal LSFBCK_PHASE to “0”.

In a case where the sign of the error in the frequency of the clock signal VCOCK at the time of the completion of the calibration is positive, the control circuit CC calculates the setting value of the counter CTR based on the frequency of the clock signal VCOCK at the time of the completion of the calibration. A method of calculating the setting value of the counter CTR will be described later. The control circuit CC sets the most significant 1 bit of the control signal LSFBCK_PHASE to “1”, and transfers the setting value of the counter CTR by a signal with a lower 8-bit width of the control signal LSFBCK_PHASE.

Note that the control circuit CC can be configured as a digital circuit. The phase comparator circuit PFD, the charge pump circuit CP, the loop filter LF, the voltage control oscillation circuit VCO, the frequency divider circuit DIVC, the calibration power supply PC, and the like are analog circuits.

In the frequency divider circuit DIVC, each signal is transferred as described below.

When the enable signal EN_CAL is deasserted by the completion of the calibration, the reset release is performed on the flip-flop FF1, the flip-flop FF2, the flip-flop FF3, and the flip-flop FF4. Then, the flip-flop FF1 fetches “1” at the timing of an initial rising edge (referred to as a first edge) of the reference clock signal REFCK after the reset release. The flip-flop FF2 fetches “1” at the timing of an initial falling edge (referred to as a second edge) of the reference clock signal REFCK after the first edge. The flip-flop FF3 fetches “1” at the timing of an initial rising edge (referred to as a third edge) of the reference clock signal REFCK after the second edge. The flip-flop FF4 fetches “1” at the timing of an initial falling edge (referred to as a fourth edge) of the reference clock signal REFCK after the second edge.

The enable signal EN_PLL is asserted at the timing earlier than the enable signal EN_CAL is deasserted (see time t1 and time t2 in FIG. 3). Therefore, at the timing of the third edge, the reset release of the flip-flop FF5 and the flip-flop FF6 has already been performed. Then, the flip-flop FF5 fetches “1” at the timing of an initial rising edge of the high-speed feedback clock signal HSFBCK immediately after the reset release, and the flip-flop FF6 fetches “1” at the timing of the next rising edge of the high-speed feedback clock signal HSFBCK. The reset release of the flip-flop FF7, the flip-flop FF8, the flip-flop FF9, and the flip-flop FF10 is performed by the signal indicating “1” fetched by the flip-flop FF6.

As in the flip-flop FF5 and the flip-flop FF6, the reset release of the flip-flop FF7, the flip-flop FF8, the flip-flop FF9, and the flip-flop FF10 is performed at the timing earlier than the timing of the third edge.

The signal indicating “1” fetched by the flip-flop FF3 is delayed by a time corresponding to approximately two cycles of the high-speed feedback clock signal HSFBCK by the flip-flop FF7 and the flip-flop FF8 for which the reset release has already been performed, and is input to the reset terminal of the programmable frequency divider PDIV as a reset release signal RSTN_PDIV.

In other words, the reset release of the programmable frequency divider PDIV and the counter CTR is performed at the timing delayed from the timing of the third edge by a time corresponding to approximately two cycles of the high-speed feedback clock signal HSFBCK.

In a case where the sign of the error in the frequency of the clock signal VCOCK at the time of the completion of the calibration is negative, the setting value of the counter CTR is set to “0”. Therefore, the count value of the counter CTR has already reached the setting value “0” at the time of the reset release, and the programmable frequency divider PDIV starts generating and outputting the low-speed feedback clock signal LSFBCK from the timing of an initial rising edge of the high-speed feedback clock signal HSFBCK after the reset release. Thus, the frequency divider circuit DIVC starts outputting the low-speed feedback clock signal LSFBCK at the timing delayed from the timing of the third edge of the reference clock signal REFCK by a time corresponding to approximately three cycles of the high-speed feedback clock signal HSFBCK. As a result, the initial phase error of the low-speed feedback clock signal LSFBCK is adjusted to a negative amount.

In a case where the sign of the error in the frequency of the clock signal VCOCK at the time of the completion of the calibration is positive, the setting value of the counter CTR is set to a specific value. The counter CTR starts counting the clock pulses of the high-speed feedback clock signal HSFBCK in response to the reset release. When the count value reaches the setting value, the programmable frequency divider PDIV starts generating and outputting the low-speed feedback clock signal LSFBCK. Thus, in a case where the setting value of the counter CTR is expressed as Nₛₑₜ, the frequency divider circuit DIVC starts outputting the low-speed feedback clock signal LSFBCK at the timing delayed from the timing of the third edge of the reference clock signal REFCK by a time corresponding to approximately (3+Nₛₑₜ) cycles of the high-speed feedback clock signal HSFBCK.

The control circuit CC determines Nₛₑₜ such that a time corresponding to (3+Nₛₑₜ) cycles of the high-speed feedback clock signal HSFBCK is slightly shorter than the cycle of the reference clock signal REFCK. For example, a small positive integer value dN (for example, dN=2) is set in the control circuit CC in advance, and the control circuit CC determines Nₛₑₜ such that a time corresponding to (3+Nₛₑₜ+dN) cycles is approximately equal to the cycle of the reference clock signal REFCK. In this way, in a case where the timing of an initial rising edge (referred to as a fifth edge) of the reference clock signal REFCK after the third edge is used as a reference, the frequency divider circuit DIVC starts outputting the low-speed feedback clock signal LSFBCK at the timing earlier by a time corresponding to approximately dN cycles of the high-speed feedback clock signal HSFBCK from the timing of the fifth edge. As a result, the initial phase error of the low-speed feedback clock signal LSFBCK is adjusted to a positive amount.

Note that the sign of the frequency error of the low-speed feedback clock signal LSFBCK is equal to the sign of the frequency error of the clock signal VCOCK. Therefore, in a case where the sign of the initial frequency error of the low-speed feedback clock signal LSFBCK is positive, the initial phase error is adjusted such that the sign of the initial phase error of the low-speed feedback clock signal LSFBCK becomes positive, and in a case where the sign of the initial frequency error of the low-speed feedback clock signal LSFBCK is negative, the initial phase error is adjusted such that the sign of the initial phase error of the low-speed feedback clock signal LSFBCK becomes negative.

The enable signal PFDEN is generated based on the timing of the second edge or the fourth edge.

In a case where the sign of the error in the frequency of the clock signal VCOCK at the time of the completion of the calibration is negative, “0” is input to the selector SEL2 as the selection signal. Therefore, the selector SEL2 selects the signal of “1” fetched by the flip-flop FF2 at the timing of the second edge. The signal of “1” fetched by the flip-flop FF2 at the timing of the second edge is delayed by the flip-flop FF9 and the flip-flop FF10 by a time corresponding to approximately two cycles of the high-speed feedback clock signal HSFBCK. Then, the delayed signal of “1” is output from the frequency divider circuit DIVC as the enable signal PFDEN. The frequency divider circuit DIVC asserts the enable signal PFDEN at the timing delayed from the timing of the second edge of the reference clock signal REFCK by a time corresponding to approximately two cycles of the high-speed feedback clock signal HSFBCK.

In a case where the sign of the error in the frequency of the clock signal VCOCK at the time of the completion of the calibration is positive, “1” is input to the selector SEL2 as the selection signal. Therefore, the selector SEL2 selects the signal of “1” fetched by the flip-flop FF4 at the timing of the fourth edge. The signal of “1” fetched by the flip-flop FF4 at the timing of the fourth edge is delayed by the flip-flop FF9 and the flip-flop FF10 by a time corresponding to approximately two cycles of the high-speed feedback clock signal HSFBCK. Then, the delayed signal of “1” is output from the frequency divider circuit DIVC as the enable signal PFDEN. Thus, the frequency divider circuit DIVC asserts the enable signal PFDEN at the timing delayed from the timing of the fourth edge of the reference clock signal REFCK by a time corresponding to approximately two cycles of the high-speed feedback clock signal HSFBCK.

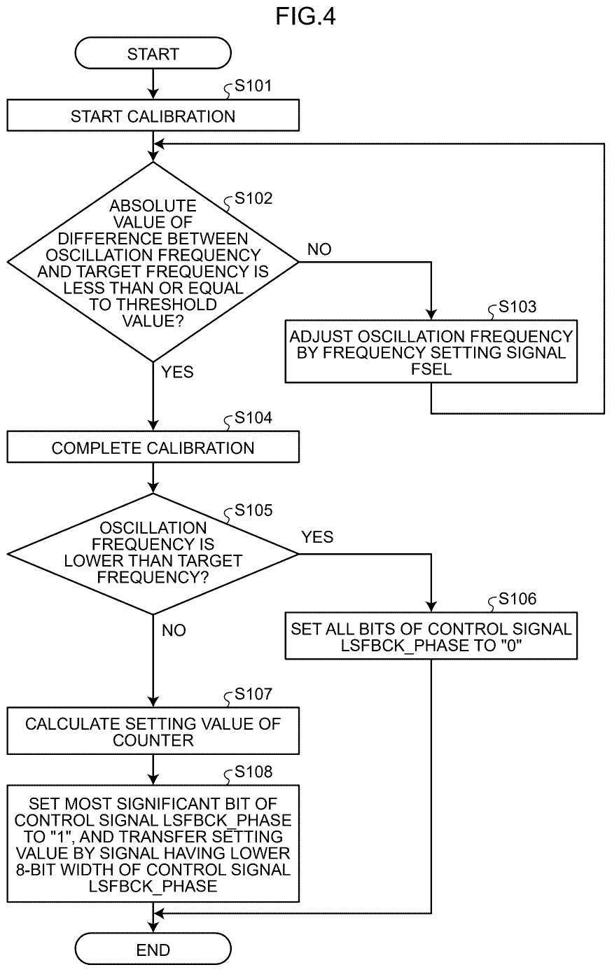

FIG. 4 is a flowchart illustrating an example of the operation of the control circuit CC according to the first embodiment.

When the calibration is started (S101), the control circuit CC determines whether the absolute value of the difference between the oscillation frequency of the voltage control oscillation circuit VCO and the target frequency of the voltage control oscillation circuit VCO is less than or equal to a predetermined threshold value (S102).

At the time of calibration, the enable signal EN_CAL is maintained at the High level. The calibration power supply PC generates a calibration potential based on the enable signal EN_CAL. The voltage control oscillation circuit VCO receives a calibration potential as a control voltage, and generates a clock signal VCOCK with a frequency corresponding to the calibration potential. In Step S102, the control circuit CC counts the frequency-divided clock pulses of the clock signal VCOCK generated based on the calibration potential. Then, the control circuit CC determines whether the absolute value of the difference between the oscillation frequency of the voltage control oscillation circuit VCO and the target frequency of the voltage control oscillation circuit VCO is equal to or less than a predetermined threshold value by comparing the count value of the frequency-divided clock pulses of the clock signal VCOCK with a predetermined setting value.

In a case where the absolute value of the difference between the oscillation frequency of the voltage control oscillation circuit VCO and the target frequency of the voltage control oscillation circuit VCO is not less than or equal to (namely, is larger than) the threshold value (S102: No), the control circuit CC adjusts the oscillation frequency of the voltage control oscillation circuit VCO corresponding to the calibration potential by the frequency setting signal FSEL (S103). Then, the control transitions to Step S102.

In a case where the absolute value of the difference between the oscillation frequency of the voltage control oscillation circuit VCO and the target frequency of the voltage control oscillation circuit VCO is less than or equal to the threshold value (S102: Yes), the calibration is completed (S104). Then, the control circuit CC determines whether the oscillation frequency of the voltage control oscillation circuit VCO at the time of the completion of the calibration is lower than the target frequency (S105).

In a case where the oscillation frequency of the voltage control oscillation circuit VCO upon completion of calibration is lower than the target frequency (S105: Yes), that is, in a case where the sign of the error of the oscillation frequency of the voltage control oscillation circuit VCO upon completion of calibration is negative, the control circuit CC sets all bits of the control signal LSFBCK_PHASE to “0” (S106). Then, the operation ends.

In a case where the oscillation frequency of the voltage control oscillation circuit VCO upon completion of calibration is not lower than the target frequency (S105: No), that is, in a case where the sign of the error of the oscillation frequency of the voltage control oscillation circuit VCO upon completion of calibration is positive or the error is 0, the control circuit CC calculates the setting value of the counter CTR (S107).

In Step S107, for example, the control circuit CC calculates the frequency of the high-speed feedback clock signal HSFBCK based on the oscillation frequency of the voltage control oscillation circuit VCO at the time of the completion of the calibration, the frequency division ratio of the frequency divider DIV1, the frequency division ratio of the frequency divider DIV2, and the frequency division ratio of the frequency divider DIV5. Then, as described above, the control circuit CC determines Nₛₑₜ based on the frequency of the high-speed feedback clock signal HSFBCK such that a time corresponding to (0 Nₛₑₜ) cycles of the high-speed feedback clock signal HSFBCK is slightly shorter than the cycle of the reference clock signal REFCK.

The control circuit CC sets the most significant bit of the control signal LSFBCK_PHASE to “1”, and transfers the setting value of the counter CTR by a signal with a lower 8-bit width of the control signal LSFBCK_PHASE (S108). Then, the operation ends.

In the example illustrated in FIG. 4, in a case where the absolute value of the difference between the oscillation frequency of the voltage control oscillation circuit VCO and the target frequency of the voltage control oscillation circuit VCO is equal to the threshold value, the control circuit CC executes the process of Step S104. In a case where the absolute value of the difference between the oscillation frequency of the voltage control oscillation circuit VCO and the target frequency of the voltage control oscillation circuit VCO is equal to the threshold value, the control circuit CC may execute the process of Step S103. In a case where the oscillation frequency of the voltage control oscillation circuit VCO at the time of the completion of the calibration is equal to the target frequency, the control circuit CC executes the process of Step S107. In a case where the oscillation frequency of the voltage control oscillation circuit VCO at the time of the completion of the calibration is equal to the target frequency, the control circuit CC may execute the process of Step S106.

Next, examples of detailed waveforms of various signals used in the frequency divider circuit DIVC according to the first embodiment will be described.

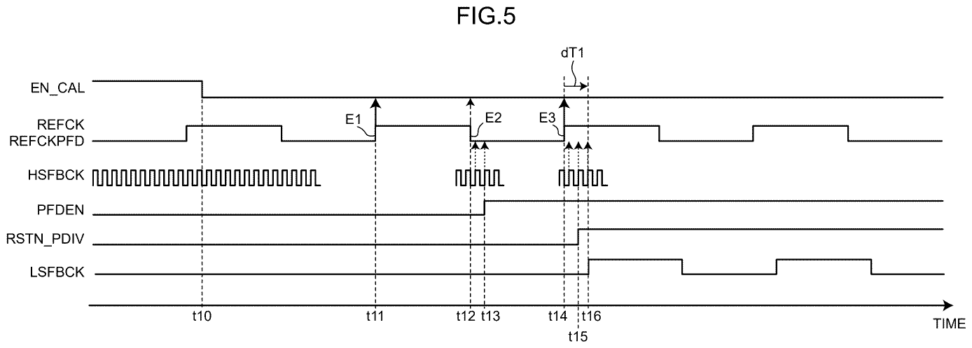

FIG. 5 is a diagram illustrating an example of detailed waveforms of various signals used in the frequency divider circuit DIVC according to the first embodiment in a case where the oscillation frequency of the voltage control oscillation circuit VCO at the time of the completion of the calibration is lower than the target frequency.

FIG. 5 illustrates respective waveforms of the enable signal EN_CAL, the reference clock signal REFCK, the reference clock signal REFCKPFD, the high-speed feedback clock signal HSFBCK, the enable signal PFDEN, the reset release signal RSTN_PDIV, and the low-speed feedback clock signal LSFBCK. The reference clock signal REFCKPFD is equivalent to the reference clock signal REFCK. Therefore, in FIG. 5, the reference clock signal REFCKPFD and the reference clock signal REFCK are collectively shown as a single waveform.

The enable signal EN_CAL is deasserted by the completion of the calibration (time t10). An initial rising edge E1 (time t11) of the reference clock signal REFCK after the enable signal EN_CAL is deasserted is the first edge. An initial falling edge E2 (time t12) after the first edge E1 is the second edge.

The enable signal PFDEN is asserted at the timing (time t13) when a time corresponding to about two clocks of the high-speed feedback clock signal HSFBCK has elapsed from the timing of the second edge E2.

An initial rising edge E3 (time t14) of the reference clock signal REFCK after the second edge E2 is the third edge. At the timing (time t15) when the high-speed feedback clock signal HSFBCK rises twice after the timing of a third edge E3, the reset release signal RSTN_PDIV is asserted. Then, the reset release is performed on the programmable frequency divider PDIV and the counter CTR.

The programmable frequency divider PDIV starts outputting the low-speed feedback clock signal LSFBCK at the timing (in other words, the timing at which the high-speed feedback clock signal HSFBCK rises three times after the timing of the third edge E3) when the high-speed feedback clock signal HSFBCK first rises after the reset release (time t16).

As described above, in the phase comparator circuit PFD, after the operation is started in response to the enable signal PFDEN, the toggle of the reference clock signal REFCKPFD at the timing of the third edge E3 is used for the first phase comparison operation. Then, after this toggling of the reference clock signal REFCKPFD, the toggling of the low-speed feedback clock signal LSFBCK is started at the timing when the high-speed feedback clock signal HSFBCK rises three times, and is used for the first phase comparison operation.

Specifically, the low-speed feedback clock signal LSFBCK in which the initial phase error is adjusted to a value with a negative sign and a magnitude corresponding to the time of about three clocks (time dT1 in FIG. 5) of the high-speed feedback clock signal HSFBCK is generated by the frequency divider circuit DIVC.

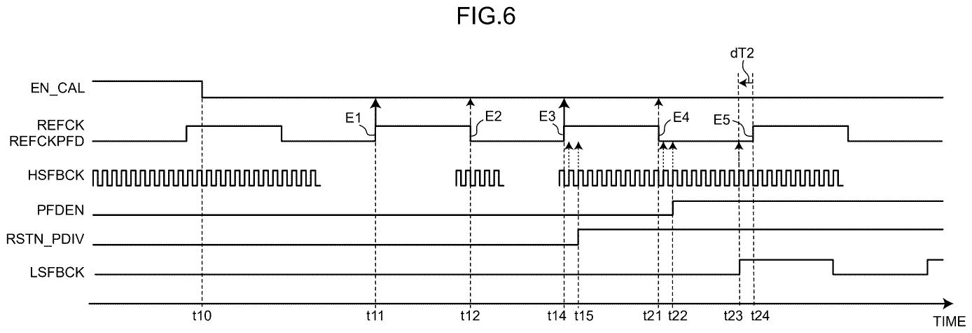

FIG. 6 is a diagram illustrating an example of detailed waveforms of various signals used in the frequency divider circuit DIVC according to the first embodiment in a case where the oscillation frequency of the voltage control oscillation circuit VCO at the time of the completion of the calibration is higher than the target frequency. FIG. 6 illustrates waveforms of various signals similar to those in FIG. 5.

Even in a case where the oscillation frequency of the voltage control oscillation circuit VCO at the time of the completion of the calibration is higher than the target frequency, the reset release signal RSTN_PDIV is asserted at the timing (time t15) when the high-speed feedback clock signal HSFBCK rises twice after the timing of the third edge E3. Then, the reset release of the programmable frequency divider PDIV and the counter CTR is performed.

The counter CTR starts counting the clock pulses of the high-speed feedback clock signal HSFBCK from time t15.

An initial falling edge E4 (time t21) of the reference clock signal REFCK after the third edge E3 is the fourth edge. The enable signal PFDEN is asserted at the timing (time t22) when the high-speed feedback clock signal HSFBCK rises twice after the timing of a fourth edge E4.

An initial rising edge E5 (time t24) of the reference clock signal REFCK after the fourth edge E4 is the fifth edge.

The setting value Nₛₑₜ of the counter CTR is determined such that a time corresponding to (3+Nₛₑₜ) cycles of the high-speed feedback clock signal HSFBCK is slightly shorter than the cycle of the reference clock signal REFCK. Therefore, the count value of the counter CTR reaches the setting value Nₛₑₜ at the timing slightly earlier than the timing of a fifth edge E5 (time t23), and the output of the low-speed feedback clock signal LSFBCK is started. Note that, in the example illustrated in FIG. 6, the output of the low-speed feedback clock signal LSFBCK is started at the timing earlier than the timing of the fifth edge E5 by a time corresponding to one to two clocks of the high-speed feedback clock signal HSFBCK.

As described above, in the phase comparator circuit PFD, after the operation is started in response to the enable signal PFDEN, the toggle of the reference clock signal REFCKPFD at the timing of the fifth edge E5 is used for the first phase comparison operation. Additionally, toggling of the low-speed feedback clock signal LSFBCK is started at the timing slightly earlier than the timing of the fifth edge E5, and is used for the first phase comparison operation.

Specifically, the low-speed feedback clock signal LSFBCK in which the initial phase error is adjusted to a value with a positive sign and a small magnitude (a value corresponding to time dT2 in FIG. 6) is generated by the frequency divider circuit DIVC.

Note that the control circuit CC may be configured to set the setting value of the counter CTR in the frequency divider circuit DIVC to a larger value Nₛₑₜ′ (>Nₛₑₜ), thereby causing the frequency divider circuit DIVC to start outputting the low-speed feedback clock signal LSFBCK at the timing later than the timing of the fifth edge E5 by a time corresponding to one to two clocks (a time shorter than time dT1 in FIG. 5) of the high-speed feedback clock signal HSFBCK. With such a configuration, it is also possible to optimize the initial phase error with a negative sign and a smaller magnitude.

As described above, according to the first embodiment, the frequency divider circuit DIVC adjusts the initial phase error based on the phase of the reference clock signal REFCKPFD after the completion of the calibration to generate the low-speed feedback clock signal LSFBCK in which the adjusted initial phase error is included.

Therefore, changes in the frequency error and the phase error due to the operation of the feedback loop are started from a point as close as possible to the center of the spiral 100 illustrated in FIG. 2. As a result, the time required for the lock-up is shortened.

Moreover, according to the first embodiment, in a case where the frequency of the clock signal VCOCK at the time of the completion of the calibration is lower than the target frequency, the frequency divider circuit DIVC adjusts the initial phase error of the low-speed feedback clock signal LSFBCK to a negative sign value. In a case where the frequency of the clock signal VCOCK at the time of the completion of the calibration is higher than the target frequency, the frequency divider circuit DIVC adjusts the initial phase error of the low-speed feedback clock signal LSFBCK to a positive sign value.

Therefore, the time required for the lock-up is further shortened.

The frequency divider circuit DIVC may not necessarily adjust the sign of the initial phase error of the low-speed feedback clock signal LSFBCK. The frequency divider circuit DIVC may be configured to adjust the initial phase error of the low-speed feedback clock signal LSFBCK to a value of predetermined one of the positive and negative signs regardless of whether the frequency of the clock signal VCOCK at the time of the completion of the calibration is lower or higher than the target frequency. In such a case, the process of generating the control signal LSFBCK_PHASE by the control circuit CC can be omitted.

In the configuration of the PLL circuit 1 described above, the flip-flop FF1, the flip-flop FF2, and the flip-flop FF3 can be regarded as a first circuit 11 that detects the third edge of the reference clock signal REFCK. The flip-flop FF7, the flip-flop FF8, and the counter CTR can be regarded as a second circuit 12 that detects the timing (denoted as the second timing) of generating and outputting the low-speed feedback clock signal LSFBCK based on the timing (denoted as the first timing) at which the third edge is detected. The programmable frequency divider PDIV can be regarded as a third circuit 13 that starts generating and outputting the low-speed feedback clock signal LSFBCK in response to the detection of the second timing by the second circuit 12.

Moreover, the second circuit 12 detects, as the second timing, a timing at which the number of edges of the high-speed feedback clock signal HSFBCK after the first timing reaches a predetermined value.

Further, the second circuit 12 determines whether the number of edges of the high-speed feedback clock signal HSFBCK after the first timing reaches a predetermined value by using the counter CTR. In a case where the frequency of the clock signal VCOCK at the time of the completion of the calibration is lower than the target frequency, the control circuit CC determines the setting value of the counter CTR such that the sign of the initial phase error becomes negative. In a case where the frequency of the clock signal VCOCK at the time of the completion of the calibration is higher than the target frequency, the control circuit CC determines the setting value of the counter CTR such that the sign of the initial phase error becomes positive.

### Second Embodiment

In a second embodiment, a configuration different from that of the first embodiment will be described. The configuration same as that of the first embodiment will not be described or will be briefly described.

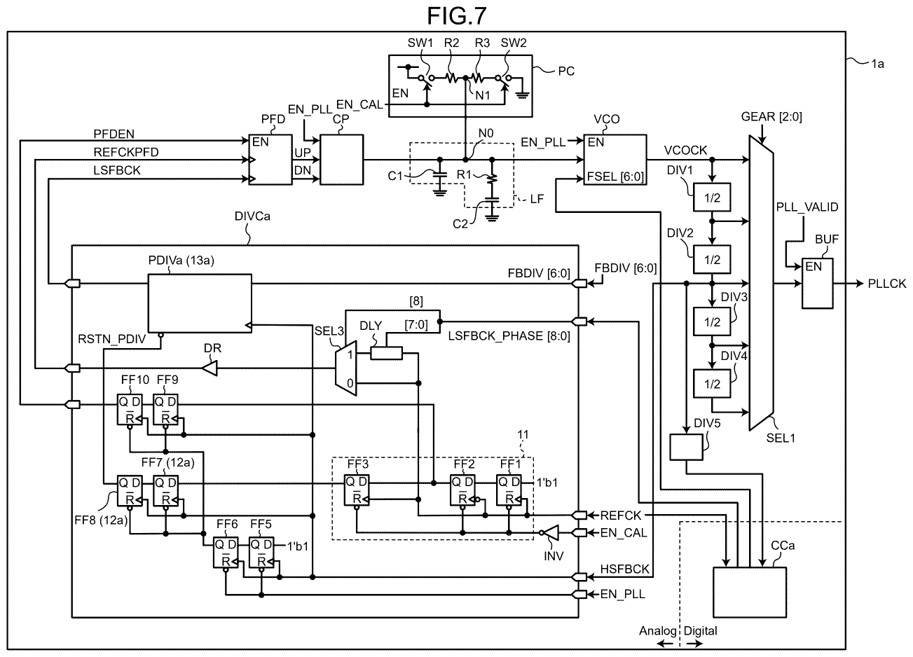

FIG. 7 is a diagram illustrating an example of a configuration of a PLL circuit 1a according to the second embodiment.

The PLL circuit 1a is different from the PLL circuit 1 according to the first embodiment in that the PLL circuit 1a includes a frequency divider circuit DIVCa instead of the frequency divider circuit DIVC and includes a control circuit CCa instead of the control circuit CC.

The frequency divider circuit DIVCa includes a programmable frequency divider PDIVa instead of the programmable frequency divider PDIV. The frequency divider circuit DIVCa does not include the flip-flop FF4, but includes a selector SEL3 and a delay circuit DLY.

The programmable frequency divider PDIVa includes the reset terminal, the clock terminal, and the control signal terminal.

The reset terminal of the programmable frequency divider PDIVa is connected to the Q terminal of the flip-flop FF8. The reset release of the programmable frequency divider PDIVa is performed by a reset release signal RSTN_PDIV output from the Q terminal of the flip-flop FF8. The high-speed feedback clock signal HSFBCK is input to the clock terminal of the programmable frequency divider PDIVa. The control signal FBDIV is input to the control signal terminal of the programmable frequency divider PDIVa.

When the reset release is completed, the programmable frequency divider PDIVa starts processing that includes: performing frequency-division at a frequency division ratio from the timing of the rising edge of the first high-speed feedback clock signal HSFBCK after the reset release, and outputting a signal generated by the frequency division of the high-speed feedback clock signal HSFBCK.

The D terminal of the flip-flop FF9 is connected to the Q terminal of the flip-flop FF2.

The selector SEL3 includes two input terminals, one output terminal, and a selection signal terminal. The reference clock signal REFCK is directly input to one of the two input terminals of the selector SEL3. The reference clock signal REFCK is input to the other of the two input terminals of the selector SEL3 via the delay circuit DLY.

A 1-bit election signal is input to the selection signal terminal of the selector SEL3. One of the signals input to the two input terminals of the selector SEL3 is selected by the selection signal, and the selected signal is output from the output terminal. In one example, in a case where the selection signal is “0”, the directly input reference clock signal REFCK is selected, and in a case where the selection signal is “1”, the reference clock signal REFCK delayed by the delay circuit DLY is selected.

An output terminal of the selector SEL3 is connected to an input terminal of the driver DR. The reference clock signal REFCK that is output from the output terminal of the driver DR and is delayed or not delayed by the delay circuit DLY is input to the phase comparator circuit PFD as the reference clock signal REFCKPFD.

The delay circuit DLY is configured such that a delay amount is settable. The delay circuit DLY delays the input reference clock signal REFCK by a set delay amount to output the delayed reference clock signal REFCK.

The control signal LSFBCK_PHASE is generated by the control circuit CCa. The control signal LSFBCK_PHASE is a signal obtained by bit-combining the selection signal of the selector SEL3 and the delay amount setting value of the delay circuit DLY. In one example, the control signal LSFBCK_PHASE is a signal with a 9-bit width. Thus, the control signal LSFBCK_PHASE transfers 9-bit information. The lower 8 bits of the control signal LSFBCK_PHASE are input to the delay circuit DLY as a delay amount setting value of the delay circuit DLY, and the most significant 1 bit of the control signal LSFBCK_PHASE is input to the selector SEL3 as a selection signal.

In the second embodiment, as in the programmable frequency divider PDIV according to the first embodiment, the reset release of the programmable frequency divider PDIVa is performed at the timing delayed from the timing of the third edge by a time corresponding to approximately two cycles of the high-speed feedback clock signal HSFBCK. After the reset release, the programmable frequency divider PDIVa starts generating and outputting the low-speed feedback clock signal LSFBCK from the timing of an initial rising edge of the high-speed feedback clock signal HSFBCK. Thus, the frequency divider circuit DIVCa starts outputting the low-speed feedback clock signal LSFBCK at the timing delayed from the timing of the third edge of the reference clock signal REFCK by a time corresponding to approximately three cycles of the high-speed feedback clock signal HSFBCK. Therefore, the initial phase of the low-speed feedback clock signal LSFBCK is delayed by an amount corresponding to the time of three cycles of the high-speed feedback clock signal HSFBCK with respect to the phase of the reference clock signal REFCK.

The delay amount setting value of the delay circuit DLY is set such that the initial phase of the low-speed feedback clock signal LSFBCK slightly advances with respect to the phase of the reference clock signal REFCKPFD. The delay amount setting value of the delay circuit DLY is calculated by the control circuit CCa.

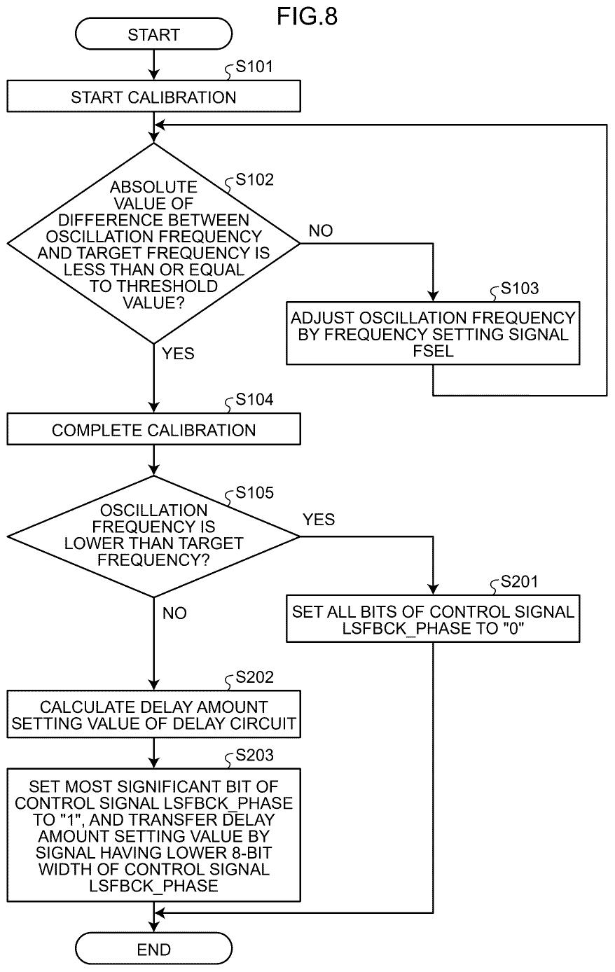

FIG. 8 is a flowchart illustrating an example of the operation of the control circuit CCa according to the second embodiment.

Also in the second embodiment, the process of Steps S101 to S105 is executed. In Step S105, the control circuit CCa determines whether the oscillation frequency of the voltage control oscillation circuit VCO at the time of the completion of the calibration is lower than the target frequency.

In a case where the oscillation frequency of the voltage control oscillation circuit VCO upon completion of calibration is lower than the target frequency (S105: Yes), that is, in a case where the sign of the error of the oscillation frequency of the voltage control oscillation circuit VCO upon completion of calibration is negative, the control circuit CCa sets all bits of the control signal LSFBCK_PHASE to “0” (S201). Then, the operation ends.

In a case where the oscillation frequency of the voltage control oscillation circuit VCO upon completion of calibration is not lower than the target frequency (S105: No), that is, in a case where the sign of the error of the oscillation frequency of the voltage control oscillation circuit VCO upon completion of calibration is positive or the error is 0, the control circuit CCa calculates a delay amount setting value of the delay circuit DLY (S202). An example of the delay amount setting value will be described later.

The control circuit CCa sets the most significant bit of the control signal LSFBCK_PHASE to “1”, and transfers the delay amount setting value of the delay circuit DLY by a signal with a lower 8-bit width of the control signal LSFBCK_PHASE (S203). Then, the operation ends.

In the example illustrated in FIG. 8, in a case where the oscillation frequency of the voltage control oscillation circuit VCO at the time of the completion of the calibration is equal to the target frequency, the control circuit CCa executes the process of Step S202. In a case where the oscillation frequency of the voltage control oscillation circuit VCO at the time of the completion of the calibration is equal to the target frequency, the control circuit CCa may execute the process of Step S201.

Next, an example of waveforms of various signals used in the frequency divider circuit DIVCa according to the second embodiment will be described. In a case where the oscillation frequency of the voltage control oscillation circuit VCO at the time of completion of the calibration is lower than the target frequency, the waveforms of the various signals are the same as the waveforms of the various signals according to the first embodiment illustrated in FIG. 5, and thus the description thereof will be omitted.

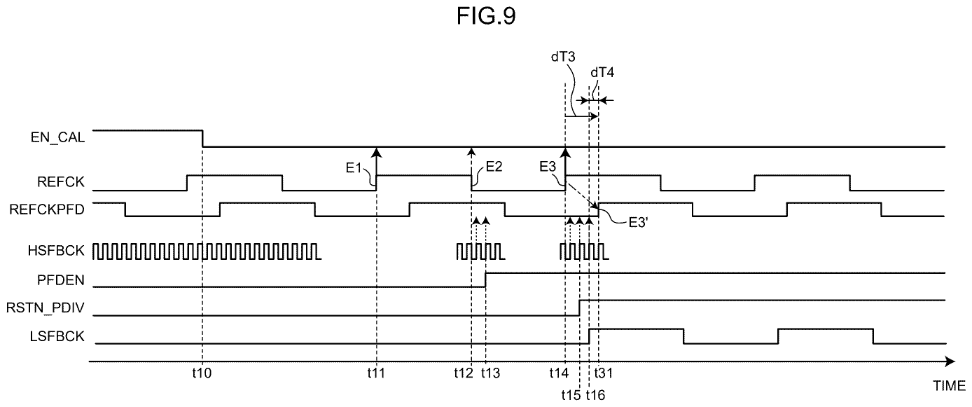

FIG. 9 is a diagram illustrating an example of detailed waveforms of various signals used in the frequency divider circuit DIVCa according to the second embodiment in a case where the oscillation frequency of the voltage control oscillation circuit VCO at the time of the completion of the calibration is higher than the target frequency.

FIG. 9 illustrates waveforms of the enable signal EN_CAL, the reference clock signal REFCK, the reference clock signal REFCKPFD, the high-speed feedback clock signal HSFBCK, the enable signal PFDEN, the reset release signal RSTN_PDIV, and the low-speed feedback clock signal LSFBCK.

The enable signal PFDEN is asserted at the timing (time t13) when a time corresponding to two clocks of the high-speed feedback clock signal HSFBCK has elapsed from the timing of the second edge E2.

The reset release signal RSTN_PDIV is asserted at the timing (time t15) when the high-speed feedback clock signal HSFBCK rises twice after the timing (time t14) of the third edge E3, whereby the reset release of the programmable frequency divider PDIVa is performed.

The programmable frequency divider PDIVa starts outputting the low-speed feedback clock signal LSFBCK at the timing (in other words, the timing at which the high-speed feedback clock signal HSFBCK rises three times after the timing of the third edge E3) when the high-speed feedback clock signal HSFBCK first rises after the reset release (time t16).

The reference clock signal REFCK is delayed by a delay amount setting value dT3 by the delay circuit DLY, whereby the reference clock signal REFCKPFD is generated. The delay amount setting value dT3 is determined by the control circuit CCa such that the third edge E3 is slightly delayed from the timing (that is, time t16 in FIG. 9) of starting the output of the low-speed feedback clock signal LSFBCK.

In the phase comparator circuit PFD, after the operation is started in response to the enable signal PFDEN, the toggle of the reference clock signal REFCKPFD at the timing (time t31) of the third edge E3', which is the third edge E3 whose timing is delayed, is used for the first phase comparison operation. The timing of the third edge E3′ is later by a slight time (time dT4 in the example of FIG. 9,) than the timing at which the toggling of the low-speed feedback clock signal LSFBCK is started.

In other words, the frequency divider circuit DIVCa generates the low-speed feedback clock signal LSFBCK including the initial phase error that has a positive sign and has been adjusted to a small amount (an amount corresponding to time dT4 in FIG. 9).

As described above, according to the second embodiment, the frequency divider circuit DIVCa includes the delay circuit DLY, and adjusts the initial phase error by using the delay circuit DLY.

Therefore, the time required for the lock-up can be shortened.

Also in the second embodiment, the frequency divider circuit DIVCa adjusts the sign of the initial phase error of the low-speed feedback clock signal LSFBCK. As a result, the time required for the lock-up is shortened.

However, the frequency divider circuit DIVCa may not necessarily adjust the sign of the initial phase error of the low-speed feedback clock signal LSFBCK. The frequency divider circuit DIVCa may be configured to adjust the initial phase error of the low-speed feedback clock signal LSFBCK to a value of predetermined one of the positive and negative signs regardless of whether the frequency of the clock signal VCOCK at the time of the completion of the calibration is lower or higher than the target frequency. In such a case, the process of generating the control signal LSFBCK_PHASE by the control circuit CCa can be omitted.

In the configuration of the PLL circuit 1a described above, the flip-flop FF1, the flip-flop FF2, and the flip-flop FF3 can be regarded as the first circuit 11 that detects the third edge of the reference clock signal REFCK. The flip-flop FF7 and the flip-flop FF8 can be regarded as the second circuit 12a that detects the timing (referred to as the second timing) of generating and outputting the low-speed feedback clock signal LSFBCK based on the timing at which the third edge is detected (referred to as the first timing). The programmable frequency divider PDIVa can be regarded as a third circuit 13a that starts generating and outputting the low-speed feedback clock signal LSFBCK in response to detection of the second timing by the second circuit 12a.

The frequency divider circuit DIVCa includes the delay circuit DLY. The control circuit CCa controls an amount of delay or an amount of advance of the reference clock signal REFCKPFD based on the second timing by using the delay circuit DLY.

Basically, in a case where the frequency of the clock signal VCOCK at the time of the completion of the calibration is lower than the target frequency, the control circuit CCa sets all bits of the control signal LSFBCK_PHASE to “0”, thereby selecting the reference clock signal REFCK that does not pass through the delay circuit DLY as the reference clock signal REFCKPFD, and performing control such that the sign of the initial phase error becomes negative. In this case, the magnitude of the initial phase error is a corresponding to approximately three cycles of the high-speed feedback clock signal HSFBCK. In a case where the frequency of the clock signal VCOCK at the time of the completion of the calibration is lower than the target frequency, the control circuit CCa can also set the most significant bit of the control signal LSFBCK_PHASE to “1” and set the lower 8 bits of the control signal LSFBCK_PHASE such that the sign of the initial phase error becomes negative and the magnitude is minimized. Thus, it is also possible to optimally control the amount of advance of the reference clock signal REFCKPFD with reference to the second timing. In a case where the frequency of the clock signal VCOCK at the time of the completion of the calibration is higher than the target frequency, the control circuit CCa optimally controls the amount of delay of the reference clock signal REFCKPFD based on the second timing by the control signal LSFBCK_PHASE such that the sign of the initial phase error becomes positive.

While certain embodiments have been described, these embodiments have been presented by way of example only, and are not intended to limit the scope of the inventions. Indeed, the novel embodiments described herein may be embodied in a variety of other forms; moreover, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
an oscillation circuit configured to oscillate a clock signal with a frequency corresponding to a potential of a control signal;
a control circuit configured to execute calibration of a first frequency when a potential of the control signal is set to a calibration potential, the first frequency being a frequency of a first clock signal, the first clock signal being the clock signal oscillated by the oscillation circuit;
a frequency divider circuit configured to, after completion of the calibration,
adjust an initial phase error based on a phase of a reference clock signal, and
generate a second clock signal being a clock signal obtained by performing frequency-division of the first clock signal to include the adjusted initial phase error;
a phase comparator circuit configured to, after completion of the calibration, compare phases between the reference clock signal and the second clock signal;
a charge pump circuit configured to, after completion of the calibration, supply a current corresponding to a result of the comparison; and
a filter circuit configured to, after completion of the calibration, convert a current from the charge pump circuit into the control signal.

2. The semiconductor device according to claim 1, wherein the frequency divider circuit is configured to
adjust the initial phase error to a negative sign value in a case where the first frequency at a time of the completion of the calibration is lower than a second frequency being a target frequency of the calibration, and
adjust the initial phase error to a positive sign value in a case where the first frequency is higher than the second frequency.

3. The semiconductor device according to claim 1, wherein
the frequency divider circuit includes a counter, and
the frequency divider circuit is configured to perform the adjustment of the initial phase error by using the counter.

4. The semiconductor device according to claim 2, wherein
the frequency divider circuit includes a counter, and
the frequency divider circuit is configured to perform the adjustment of the initial phase error by using the counter.

5. The semiconductor device according to claim 1, wherein
the frequency divider circuit includes a delay circuit, and
the frequency divider circuit is configured to perform the adjustment of the initial phase error by using the delay circuit.

6. The semiconductor device according to claim 2, wherein
the frequency divider circuit includes a delay circuit, and
the frequency divider circuit is configured to perform the adjustment of the initial phase error by using the delay circuit.

7. The semiconductor device according to claim 1, wherein the frequency divider circuit includes
a first circuit configured to detect an edge of the reference clock signal,
a second circuit configured to detect a second timing based on a first timing at which the edge of the reference clock signal is detected by the first circuit, and
a third circuit configured to start processing in response to the detection of the second timing, the processing including generating the second clock signal by performing frequency-division of a third clock signal and outputting the second clock signal, the third clock signal being the first clock signal or a clock signal obtained by performing frequency-division of the first clock signal, the third clock signal with a frequency higher than a frequency of the reference clock signal.

8. The semiconductor device according to claim 7, wherein the second circuit is configured to detect, as the second timing, a timing at which a number of edges of the third clock signal after the first timing reaches a setting value.

9. The semiconductor device according to claim 8, wherein the control circuit is configured to
determine whether the first frequency at a time of completion of the calibration is lower or higher than a second frequency being a target frequency of the calibration,
determine the setting value causing a sign of the initial phase error to become negative in a case where the first frequency is lower than the second frequency, and
determine the setting value causing a sign of the initial phase error to become positive in a case where the first frequency is higher than the second frequency.

10. The semiconductor device according to claim 7, wherein
the frequency divider circuit further includes a delay circuit, and
the control circuit is configured to control, by using the delay circuit, an amount of delay or an amount of advance of the reference clock signal based on the second timing.

11. The semiconductor device according to claim 10, wherein the control circuit is configured to
determine whether the first frequency at a time of completion of the calibration is lower or higher than a second frequency being a target frequency of the calibration,
control an amount of delay or an amount of advance of the reference clock signal to cause a sign of the initial phase error to become negative in a case where the first frequency is lower than the second frequency, and
control an amount of delay or an amount of advance of the reference clock signal to cause a sign of the initial phase error to become positive in a case where the first frequency is higher than the second frequency.

12. A method of controlling a semiconductor device, the semiconductor device including an oscillation circuit, a phase comparator circuit, a charge pump circuit, and a filter circuit, the oscillation circuit oscillating a clock signal with a frequency corresponding to a potential of a control signal, the charge pump circuit supplying a current corresponding to a signal from the phase comparator circuit, the filter circuit converting a current from the charge pump circuit into the control signal, the method comprising:
setting a potential of the control signal to a calibration potential;
executing calibration of a first frequency when the potential of the control signal is set to the calibration potential, the first frequency being a frequency of a first clock signal, the first clock signal being the clock signal oscillated by the oscillation circuit;
after completion of the executing calibration,
adjusting an initial phase error based on a phase of a reference clock signal, and
generating a second clock signal being a clock signal obtained by performing frequency-division of the first clock signal to include the adjusted initial phase error; and
causing the phase comparator circuit to compare phases between the reference clock signal and the second clock signal and output, as the signal from the phase comparator circuit, a result of the comparison of the phases.

13. The method of claim 12, further comprising:
adjusting the initial phase error to a negative sign value in a case where the first frequency at a time of the completion of the calibration is lower than a second frequency being a target frequency of the calibration; and
adjusting the initial phase error to a positive sign value in a case where the first frequency is higher than the second frequency.

14. The method of claim 12, further comprising:
adjusting the initial phase error by using a counter.

15. The method of claim 13, further comprising:
adjusting the initial phase error by using a counter.

16. The method of claim 12, further comprising:
adjusting the initial phase error by using a delay circuit.

17. The method of claim 13, further comprising:
adjusting the initial phase error by using a delay circuit.
